(19) United States
(12) Patent Application Publication
(10) Pub. No.: US 2012/0003815 A1
(43) Pub. Date: Jan. 5, 2012

(54) SEMICONDUCTOR STRUCTURE AND METHOD OF FABRICATING THE SAME

(75) Inventor: Sang-Yun Lee, Beaverton, OR (US)

(73) Assignee: BESANG INC., Beaverton, OR (US)

(21) Appl. No.: 13/175,293

(22) Filed: Jul. 1, 2011

(30) Foreign Application Priority Data
Jul. 2, 2010 (KR) 10-2009-63943

(51) Int. Cl. H01L 21/304

(52) U.S. Cl. 438/458; 257/E21.237

(57) ABSTRACT

A method of fabricating a semiconductor substrate includes providing a first semiconductor substrate, which includes a detaching layer spaced from an upper surface of the first semiconductor substrate; forming an ion-implanted layer proximate to an edge of the detaching layer; bonding a second semiconductor substrate to the first semiconductor substrate; forming a crack in the ion-implanted layer in response to applying stress to the ion-implanted layer; and detaching a portion of the first semiconductor substrate in response to cleaving through the crack.

### CROSS-REFERENCE TO RELATED APPLICATIONS

This patent application claims priority to Korean Patent Application No. 10-2009-63943, which was filed on Jul. 2, 2010, by the same inventor, the contents of which are incorporated by reference as though fully set forth herein.

### BACKGROUND OF THE INVENTION

1. Field of the Invention

This invention relates to semiconductor circuitry formed using bonding.

2. Description of the Related Art

Advances in semiconductor manufacturing technology have provided computer systems with integrated circuits that include many millions of active and passive electronic devices, along with the interconnects to provide the desired circuit connections. A typical computer system includes a computer chip, with processor and control circuits, and an external memory chip. As is well-known, most integrated circuits include laterally oriented active and passive electronic devices that are carried on a single major surface of a substrate. The current flow through laterally oriented devices is generally parallel to the single major surface of the substrate. Active devices typically include transistors and passive devices typically include resistors, capacitors, and inductors. However, these laterally oriented devices consume significant amounts of chip area. Sometimes laterally oriented devices are referred to as planar or horizontal devices. Examples of laterally oriented devices can be found in U.S. Pat. No. 6,600,173 to Tiwari, U.S. Pat. No. 6,222,251 to Holloway and U.S. Pat. No. 6,331,468 to Aronowitz.

Vertically oriented devices extend in a direction that is generally perpendicular to the single major surface of the substrate. The current flow through vertically oriented devices is generally perpendicular to the single major surface of the substrate. Hence, the current flow through a vertically oriented semiconductor device is generally perpendicular to the current flow through a horizontally oriented semiconductor device. Examples of vertically oriented semiconductor device can be found in U.S. Pat. No. 5,106,775 to Kaga, U.S. Pat. No. 6,229,161 to Nemati, U.S. Pat. No. 7,078,739 to Nemati. It should be noted that U.S. Pat. No. 5,554,870 to Fitch, U.S. Pat. No. 6,229,161 to Nemati and U.S. Pat. No. 7,078,739 to Nemati disclose the formation of both horizontal and vertical semiconductor devices on a single major surface of a substrate.

It is desirable to provide computer chips that can operate faster so that they can process more data in a given amount of time. The speed of operation of a computer chip is typically measured in the number of instructions in a given amount of time it can perform. Computer chips can be made to process more data in a given amount of time in several ways. For example, they can be made faster by decreasing the time it takes to perform certain tasks, such as storing and retrieving information to and from the memory chip. The time needed to store and retrieve information to and from the memory chip can be decreased by embedding the memory devices included therein with the computer chip. This can be done by positioning the memory devices on the same surface as the other devices carried by the substrate.

However, there are several problems with doing this. One problem is that the masks used to fabricate the memory devices are generally not compatible with the masks used to fabricate the other devices on the computer chip. Hence, it is more complex and expensive to fabricate a computer chip with memory embedded in this way. Another problem is that memory devices tend to be large and occupy a significant amount of area. Hence, if most of the area on the computer chip is occupied by memory devices, then there is less area for the other devices. Further, the yield of the computer chips fabricated in a run decreases as their area increases, which increases the overall cost.

Instead of embedding the memory devices on the same surface as the other devices, the memory chip can be bonded to the computer chip to form a stack, as in a 3-D package or a 3-D integrated circuit (IC). Conventional 3-D packages and 3-D ICs both include a substrate with a memory circuit bonded to it by a bonding region positioned therebetween. The memory chip typically includes lateral memory devices which are prefabricated before the bonding takes place. In both the 3-D package and 3-D ICs, the memory and computer chips include large bonding pads coupled to their respective circuits. However, in the 3-D package, the bonding pads are connected together using wire bonds so that the memory and computer chips can communicate with each other. In the 3-D IC, the bonding pads are connected together using high pitch conductive interconnects which extend therebetween. Examples of 3-D ICs are disclosed in U.S. Pat. Nos. 5,087,585, 5,308,782, 5,355,022, 5,915,167, 5,998,808 and 6,943,067.

There are several problems, however, with using 3-D packages and 3-D ICs. One problem is that the use of wire bonds increases the access time between the computer and memory chips because the impedance of wire bonds and large contact pads is high. The contact pads are large in 3-D packages to make it easier to attach the wire bonds thereto. Similarly, the contact pads in 3-D ICs have correspondingly large capacitances which also increase the access time between the processor and memory circuits. The contact pads are large in 3-D ICs to make the alignment between the computer and memory chips easier. These chips need to be properly aligned with each other and the interconnects because the memory devices carried by the memory chip and the electronic devices carried by the computer chip are prefabricated before the bonding takes place.

Another problem with using 3-D packages and 3-D ICs is cost. The use of wire bonds is expensive because it is difficult to attach them between the processor and memory circuits and requires expensive equipment. Further, it requires expensive equipment to align the various devices in the 3-D IC. The bonding and alignment is made even more difficult and expensive because of the trend to scale devices to smaller dimensions. It is also very difficult to fabricate high pitch conductive interconnects.

Some references disclose forming an electronic device, such as a dynamic random access memory (DRAM) capacitor, by crystallizing polycrystalline and/or amorphous semiconductor material using a laser. One such electronic device is described in U.S. patent Application No. 20040131233 to Bhattacharyya. The laser is used to heat the polycrystalline or amorphous semiconductor material to form a single crystalline semiconductor material. However, a disadvantage of this method is that the laser is capable of driving the temperature of the semiconductor material to be greater than 800 degrees Celsius (° C.). In some situations, the temperature of the semiconductor material is driven to be greater than about 1000 (° C.). It should be noted that some of this heat undesirably flows to other regions of the semiconductor structure proximate to the DRAM capacitor, which can cause damage.

Accordingly, it is highly desirable to provide a new method for forming electronic devices using wafer bonding which is cost effective and reliable, and can be done at low temperature.

### BRIEF SUMMARY OF THE INVENTION

The present invention involves a semiconductor circuit structure, and a method of forming the semiconductor circuit structure. The invention will be best understood from the following description when read in conjunction with the accompanying drawings.

### BRIEF DESCRIPTION OF THE DRAWINGS

FIGS. 1 to 7 are sectional views of steps in forming a semiconductor substrate, in accordance with an embodiment of this invention.

FIGS. 8 to 9 are sectional views of other methods in detaching semiconductor substrates, in accordance with an embodiment of this invention.

FIGS. 10 to 13 are sectional views of steps in forming a semiconductor device by using the semiconductor substrate, in accordance with an embodiment of this invention.

### DETAILED DESCRIPTION OF THE INVENTION

A method for fabricating a semiconductor substrate and a method for fabricating a semiconductor device by using the same, more specifically relates to a method for fabricating a semiconductor substrate and a method for fabricating a semiconductor device by using the same more reliable and repeatable is provided. The method is comprised of, providing a first semiconductor substrate including a detaching layer in a pre-defined depth from the surface; forming ion-implanted layer around edge of the detaching layer; bonding a second semiconductor substrate to the first semiconductor substrate; forming crack in the ion-implanted layer by adding stress to the ion-implanted layer; and detaching portion of the first semiconductor substrate by spreading out the crack from the ion-implanted layer through the detaching layer, and also the method is comprised of providing a first semiconductor substrate including a detaching layer in a pre-defined depth from the surface; forming ion-implanted layer around edge of the detaching layer; bonding a second semiconductor substrate on surface of the first semiconductor substrate, wherein the second semiconductor substrate includes semiconductor devices and an isolation layer which covers the semiconductor devices on top; adding stress to the ion-implanted layer to create crack in the ion-implanted layer; detaching a portion of the first semiconductor substrate by spreading out the crack from the ion-implanted layer through the detaching layer; and forming second semiconductor devices on the first semiconductor substrate which is remained on the surface of the second semiconductor substrate. More information regarding the method disclosed herein can be found in U.S. patent application Ser. Nos. 12/581,722, 12/874,866 and 12/847,374, by the same inventor, the contents of which are incorporated by reference as though fully set forth herein.

More information regarding some of the steps disclosed herein can be found in U.S. Pat. Nos. 7,052,941, 7,378,702, 7,470,142, 7,470,598, 7,632,738, 7,633,162, 7,671,371, 7,718,508, 7,799,675, 7,800,199, 7,846,814, 7,867,822, 7,888,764, the contents of which are incorporated by reference as though fully set forth herein. More information regarding some of the steps disclosed herein can be found in U.S. Patent Application Nos. 20050280154, 20050280155, 20050280156, 20060275962, 20080032463, 20080048327, 20090267233, 20100038743, 20100133695, 20100190334, 20110001172, 20110003438 and 20110053332, the contents of which are incorporated by reference as though fully set forth herein.

More information regarding some of the steps disclosed herein can be found in U.S. Pat. Nos. 5,250,460, 5,277,748, 5,374,564, 5,374,581, 5,695,557, 5,854,123, 5,882,987, 5,980,633, 6,103,597, 6,380,046, 6,380,099, 6,423,614, 6,534,382, 6,638,834, 6,653,209, 6,774,010, 6,806,171, 6,809,009, 6,864,534, 7,067,396, 7,148,119, 7,256,104, RE39,484, as well as in U.S. Patent Application Nos. 20030205480, 20030224582 and 20070190746, the contents of which are incorporated by reference as though fully set forth herein.

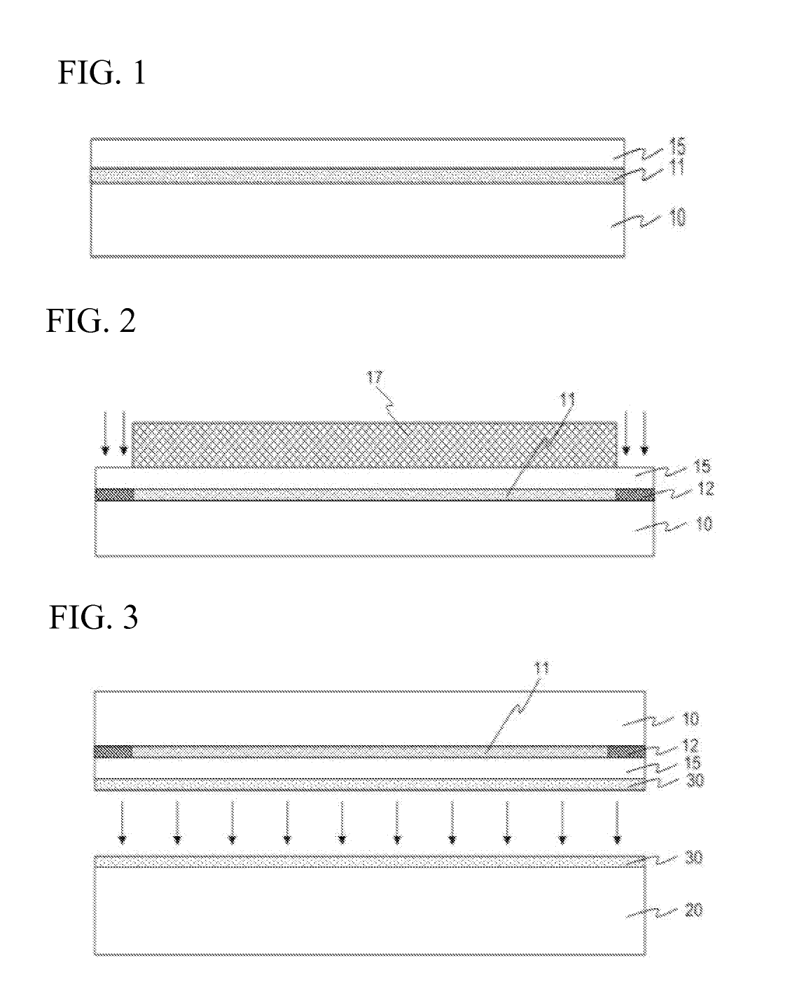

FIGS. 1 to 7 are sectional views of steps in forming a semiconductor substrate, in accordance with an embodiment of this invention. As illustrated in FIG. 1, a single crystalline semiconductor substrate 10 is provided which will be bonded to a base substrate. The single crystalline semiconductor substrate 10 can be a blank wafer.

A detaching layer 11 is formed on the single crystalline semiconductor substrate. The detaching layer 11 can be a porous layer which includes micro pores in the layer. The detaching layer 11 can be formed to have very small diameter cavities by anodizing silicon substrate in the HF solution (Hydrofluoric Acid). The detaching layer 11 includes many crystal structure defects in crystal so that the defects the defective crystal structure enables precise and easy detaching of the single crystalline semiconductor substrate 10 after bonding to the base substrate. A single crystalline epitaxial layer 15 can be formed on the detaching layer 11 by epitaxial growth process.

FIG. 2 illustrates steps of forming a mask pattern 17 exposing edge region on the single crystalline epitaxial layer 15. The mask pattern 17 can be also physical or mechanical structure.

The mask pattern 17 can be circular shape which has a smaller diameter than the single crystalline semiconductor substrate 10 which is also a circular shape. By locating the mask pattern 17 on the single crystalline semiconductor substrate 10, the edge of the single crystalline epitaxial layer 15 can be exposed.

As following steps, gas-phase gases such as Hydrogen can be ion-implanted to the detaching layer 11 using the mask pattern 17 as ion-implant mask so that a ion-implanted layer 12 is formed. The ion-implanted layer 12 can aid detaching of the single crystalline semiconductor substrate 10 after bonding the single crystalline epitaxial layer 15 and the base substrate.

By forming the ion-implanted layer 12 only in the edge of the detaching layer 11 while masking inner region of the single crystalline epitaxial layer 15 using the mask pattern 17, crystal lattice structure of the single crystalline epitaxial layer 15 can be protected during the ion-implantation process.

The mask pattern 17 on the single crystalline epitaxial layer 15 is removed after forming the ion-implanted layer 12.

FIG. 3 illustrates steps of providing base substrate 20 and forming detaching layer on each of the single crystalline epitaxial layer 15 and base substrate 20.

The base substrate 20 can be bulk silicon, bulk silicon-germanium, or silicon or silicon-germanium epitaxial layer grown on the bulk silicon or bulk silicon-germanium substrate. Also, the first semiconductor substrate 100 can include silicon-on-saphire(SOS), silicon-on-insulator(SOI), thin film transistor(TFT), doped or undoped semiconductors, silicon epitaxial layer on the base semiconductor substrate, or any other semiconductor materials that are well known to those skilled in the art.

A bonding layer 30 can be formed with, for example, photo-setting adhesive such as reaction-setting adhesive, thermal-setting adhesive, photo-setting adhesive such as UV-setting adhesive, or anaerobe adhesive. Further, the bonding layer can be, such as, metallic bonds(Ti, TiN, Al), epoxy, acrylate, or silicon adhesives. The bonding layer 30 can be used to increase bonding strength when bonding the base substrate 20 on the bonding layer 30, and also can be used to decrease micro defects which can be occurred during the bonding process.

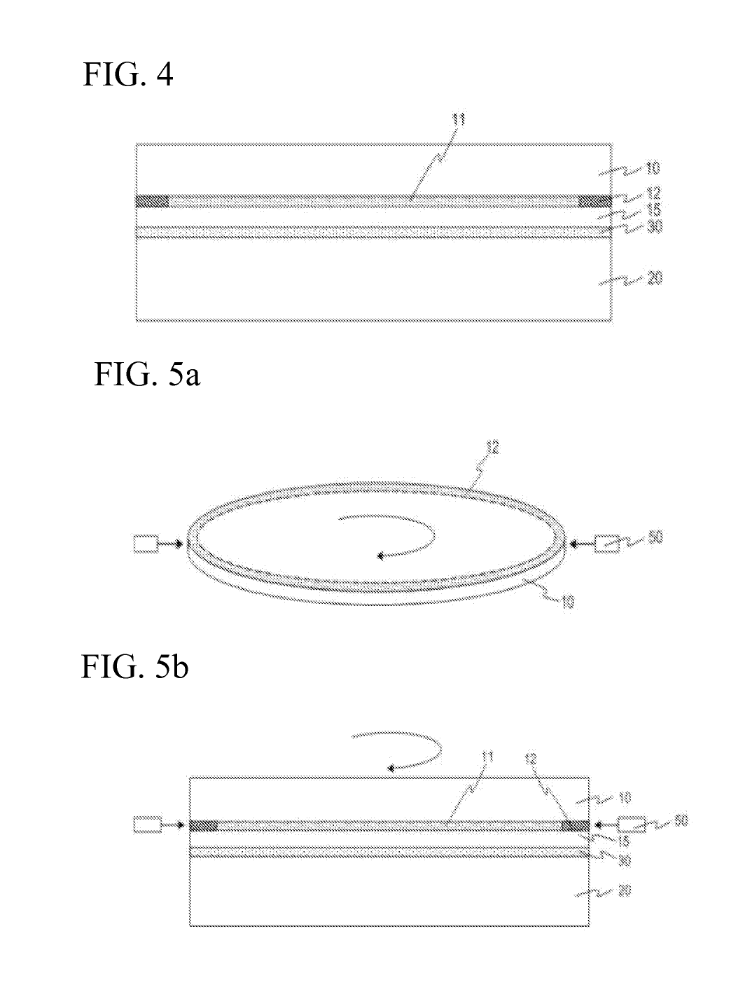

As shown in FIG. 4, the bonding layer 30 on the single crystalline epitaxial layer 15 and the bonding layer 30 on the base substrate 20 are bonded each other. A thermal treatment under certain pressure can be performed to increase bonding strength after bonding the single crystalline semiconductor substrate 10 on the base substrate 20. As a result, a stacked structure of the single crystalline epitaxial layer 15, the detaching layer 11 and the single crystalline semiconductor substrate 10 can be formed on the base substrate 20.

FIGS. 5 and 5a illustrate a method of adding stress to sidewall of single crystalline semiconductor substrate 10 into the locally formed ion-implanted layer 12 in order to create crack at the boundary of single crystalline semiconductor substrate 10 and the single crystalline epitaxial layer 15, i.e. the ion-implanted layer 12, which is formed at the edge of the detaching layer 11, is cracked.

For example, in order to detach the single crystalline semiconductor substrate 10, a laser 50 can be irradiated to the sidewall of the ion-implanted layer 12 and locally heat up the ion-implanted layer 12. The laser 50 can heat up the ion-implanted layer 12 at the temperature of 350˜600 degree Celsius so that a crack is formed in the boundary of single crystalline semiconductor substrate 10 and the single crystalline epitaxial layer 15. Specifically, by locally heating up the ion-implanted layer 12, the volume of a cavity that comprises the detaching layer 11 is expanded and the expansion creates crack in the detaching layer 11.

Also, a high pressure waterjet can be injected into the sidewall of the ion-implanted layer 12 to add physical shock to the sidewall of the ion-implanted layer 12 so that a crack is formed in the boundary of single crystalline semiconductor substrate 10 and the single crystalline epitaxial layer 15.

The base substrate 20 on which the single crystalline semiconductor substrate 10 is bonded can be rotated while irradiating the laser 50 or injecting the waterjet in order to uniformly adding the stress to the ion-implanted layer 12 which is locally formed in the edge of the detaching layer 11. The laser 50 and waterjet can be arranged single or multiple around the single crystalline semiconductor substrate 10.

By adding local stress, the ion-implanted layer 12 is cracked to form the crack, then the crack spreads out to the detaching layer 11 continuously along with the area where crystal lattice structure is weak, as a result the single crystalline semiconductor substrate 10 and the single crystalline epitaxial layer 15 can be detached.

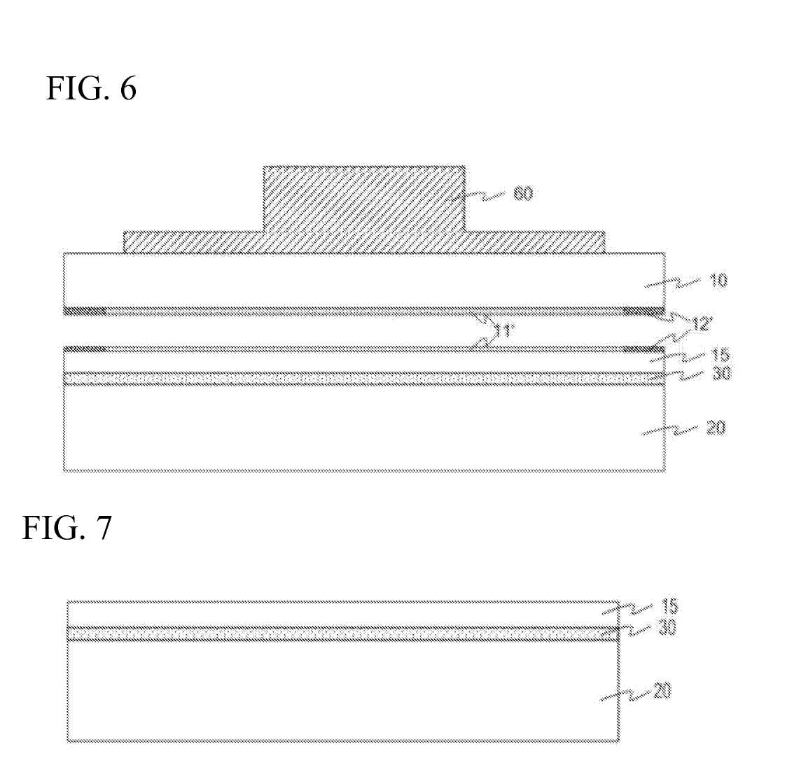

As shown in FIG. 6, a vacuum chuck 60 is used to suck to the single crystalline semiconductor substrate 10 on the single crystalline epitaxial layer 15, to detach the single crystalline semiconductor substrate 10. After detaching the single crystalline semiconductor substrate 10 from the top of the single crystalline epitaxial layer 15, the detaching layer 11 and the ion-implanted layer 12 can be remained on the single crystalline epitaxial layer 15. The surface of the single crystalline epitaxial layer 15 can be treated subsequently. A grinding or polishing process can be performed to the surface of the single crystalline epitaxial layer 15 in order to remove the detaching layer 11 and the ion-implanted layer 12 that are remained on the single crystalline epitaxial layer 15. In other method, the surface of the single crystalline epitaxial layer 15 can be etched isotropic or anisotropic. For example, wet-etching the single crystalline epitaxial layer 15 using diluted Hydrofluoric acid, a naturally grown oxide or contaminations on the surface can be removed.

By treating the surface of the single crystalline epitaxial layer 15, as shown in the FIG. 7, the surface of the single crystalline epitaxial layer 15 becomes to have good quality and remain bonded on the base substrate 20.

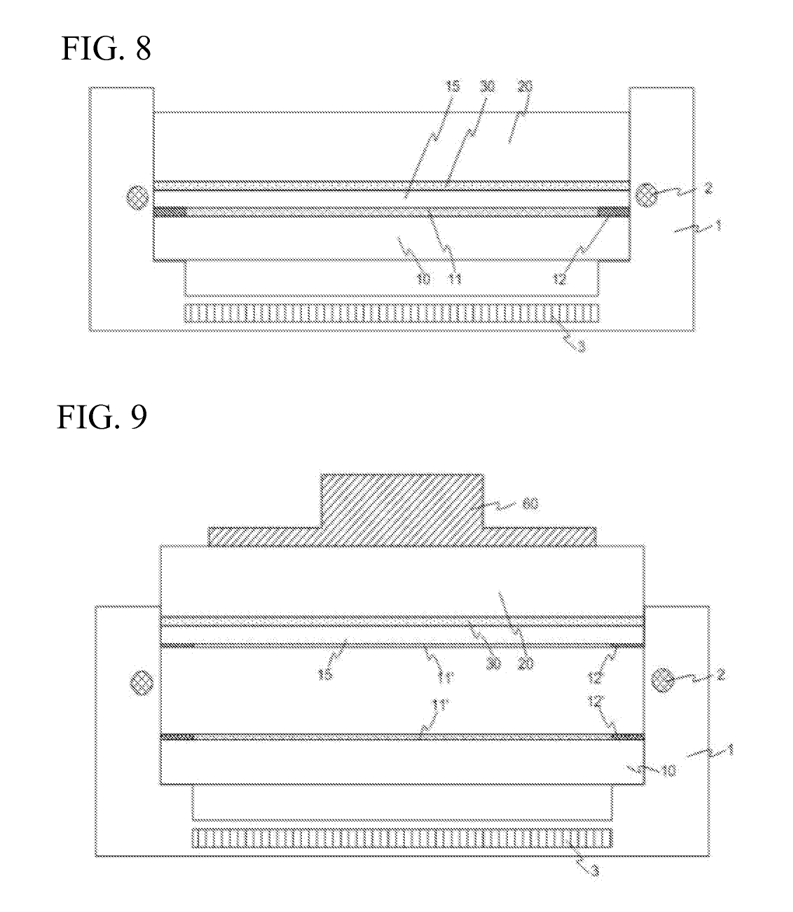

In addition to the method of detaching the single crystalline semiconductor substrate 10 and the single crystalline epitaxial layer 15 as shown FIGS. 5a and 5b, a heating apparatus shown in the FIGS. 8 and 9 can be used to detach the single crystalline semiconductor substrate 10 and the single crystalline epitaxial layer 15.

FIGS. 8 and 9 illustrate other detaching method used in other embodiment of this invention.

As shown in FIG. 8, the heating apparatus 1 comprises a heating device 2 which applies heat around the edge of the semiconductor substrate. The heating device 2 can be heating coil or heating lamp with which side of the semiconductor substrate can be heated about from 350 degree Celsius to 600 degree Celsius.

The base substrate 20, to which the single crystalline semiconductor in FIG. 4 is bonded, is arranged in the heating apparatus 1. Then the ion-implanted layer 12, which is formed edge of the between the single crystalline semiconductor substrate 10 and the single crystalline epitaxial layer 15, is heated. The circumference of sidewall of the base substrate 20, on which the single crystalline semiconductor substrate 10 is bonded, can be uniformly heated.

By heating the ion-implanted layer 12 using the heating device 2, a crack can be created in between the circumference of the single crystalline semiconductor substrate 10 and the single crystalline epitaxial layer 15.

As shown in FIG. 9, as a following step, a vacuum chuck is used to stick to the single crystalline semiconductor substrate 10 in order to detach the single crystalline epitaxial layer 15 and the single crystalline semiconductor substrate 10. In this case, by adding heat to the ion-implanted layer 12, a crack is easily created along to the weak crystal structure of the detaching layer 11. As a result, by using the vacuum chuck, the single crystalline semiconductor substrate 10 can be easily detached.

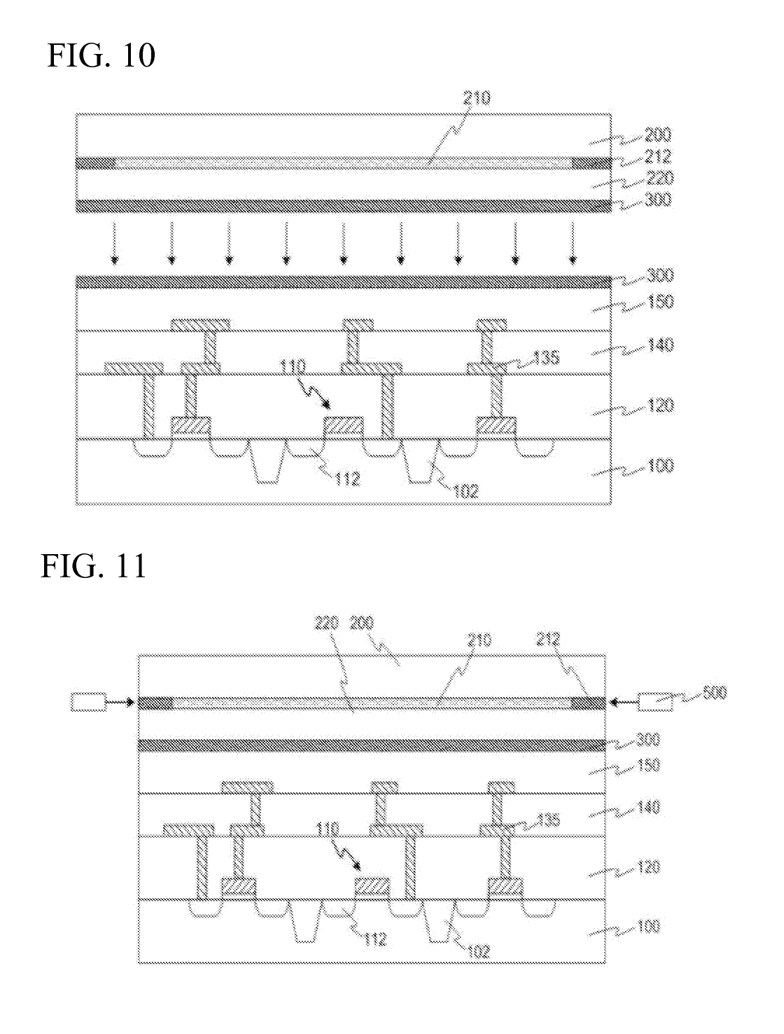

FIGS. 10 to 13 illustrate a method of fabricating 3d semiconductor device using the semiconductor substrate in accordance with an embodiment of this invention.

In FIG. 10, a first semiconductor substrate 100 is provided. The first semiconductor substrate 100 can be bulk silicon, bulk silicon-germanium, or silicon or silicon-germanium epitaxial layer grown on the bulk silicon or bulk silicon-germanium substrate. Also, the first semiconductor substrate 100 can include silicon-on-saphire(SOS), silicon-on-insulator(SOI), thin film transistor(TFT), doped or undoped semiconductors, silicon epitaxial layer on the base semiconductor substrate, or any other semiconductor materials that are well known to those skilled in the art.

As a following step, isolation films 102 are formed in order to define active region. The isolation films 102 can be formed by forming trenches in the first semiconductor substrate 100 and then filling in the trenches with isolation materials such as High Density Plasma(HDP) oxide.

Then, lower region semiconductor devices are formed on the first semiconductor substrate 100 in where active region is defined.

For example, a gate conductor 110 is formed by depositing and patterning gate dielectric film and gate conductor film. After forming the gate conductor 110, dopants are ion-implanted into the first semiconductor substrate 100 at each side of the gate conductor 110 to form source/drain region 112. As a result, transistors are formed on the first semiconductor substrate 100.

In another embodiment of this invention, wirings, capacitors, diodes and/or memory devices can be formed as lower region semiconductor devices on the first semiconductor substrate 100.

Then, a first interlayer dielectric film 120 is formed which covers transistors which has a good step coverage.

Contacts and wirings 135 are formed in the first interlayer dielectric film 120. The contacts 135 can formed by etching anisotropic the first interlayer dielectric film 120, forming contacts holes which exposes source/drain region 112 or gate conductor 110, and then filling in the holes with conducting material. The wirings 135 can be connected to the contacts 135 on the first interlayer dielectric film 120.

A multiple number of second interlayer dielectric film 140 can be formed on the first interlayer dielectric film 120.

When the contacts and wirings 135 are formed, refractory metals can be used in order to decrease thermal affect from the following process steps. That is, the contacts and wirings 135 can be of many different types, such as tungsten (W), titanium (Ti), molybdenum (Mo), tantalum (Ta), titanium nitride (TiN), tantalum nitride (TaN), zirconium nitride (ZrN), tungsten nitride, and alloys thereof.

A third interlayer dielectric film 150, which lastly covers the cell circuitry of the semiconductor memory device formed on the first semiconductor substrate 100, and deposited and then planarized.

A bonding layer 300 is formed on the third interlayer dielectric film 150, in order to provide a single crystalline semiconductor layer on which other semiconductor devices are formed. The bonding layer 300 can be photo-setting adhesive such as reaction-setting adhesive, thermal-setting adhesive, photo-setting adhesive such as UV-setting adhesive, or anaerobe adhesive. Further, the bonding layer 300 can be, for example, metallic bond (Ti, TiN, Al), epoxy, acrylate, or silicon adhesive, and desirably can be formed with titanium which has good stability at high temperature.

The bonding layer 300 can increase bonding strength when bonding a second semiconductor substrate on the bonding layer 300, and also can decrease micro defects which can be occurred during the bonding process.

Following step is bonding the second semiconductor substrate 200 (illustrated in FIGS. 1 and 2) on the third interlayer dielectric film 150 on the first semiconductor substrate 100.

A detaching layer 210 which is formed of porous layer is formed on the second semiconductor substrate 200 and then single crystalline epitaxial layer follows. At the edge boundary of the detaching layer 201, as illustrated in FIG. 2, gas phase gas such as hydrogen is ion-implanted to form a ion-implanted layer 212.

Surface of the third interlayer dielectric film 150 on the first semiconductor substrate 100 and surface of the single crystalline epitaxial layer 220 are bonded each other. A thermal treatment under pre-defined pressure can be performed after bonding the second semiconductor substrate 200 on the first semiconductor substrate 100 to increase bonding strength.

As shown in FIG. 11, crack can be created at the edge boundary interface of the second semiconductor substrate 200 and single crystalline epitaxial layer 220 by adding stress to sidewall of the locally formed ion-implanted layer 212. Specifically, the ion-implanted layer 212, which is formed at edge boundary of the detaching layer 210, can be cracked to form crack.

For example, a laser 500 can be irradiated to the sidewall of the ion-implanted layer 212 and locally heat up the ion-implanted layer 212. The laser 500 can heat up the ion-implanted layer 212 at the temperature of 350˜600 degree Celsius so that a crack is formed in the boundary of the second semiconductor substrate 200 and the single crystalline epitaxial layer 220. Also, a high pressure waterjet can be injected to the sidewall of the ion-implanted layer 212 to add physical shock to the sidewall of the ion-implanted layer 212 so that a crack can be formed in the boundary of the second semiconductor substrate 200 and the single crystalline epitaxial layer 220.

The first semiconductor substrate 100 on which the second semiconductor substrate 200 is bonded can be rotated while irradiating the laser 500 or injecting the waterjet in order to uniformly adding the stress to the ion-implanted layer 212. The laser 500 and waterjet can be arranged single or multiple numbers around the second semiconductor substrate 200.

When the crack is formed by locally added stress to the ion-implanted layer 212, the crack can be spread out along to the detaching layer 201 where crystal lattice structure is weak, and this results the detaching of the single crystalline epitaxial layer 220 and the second semiconductor substrate 200.

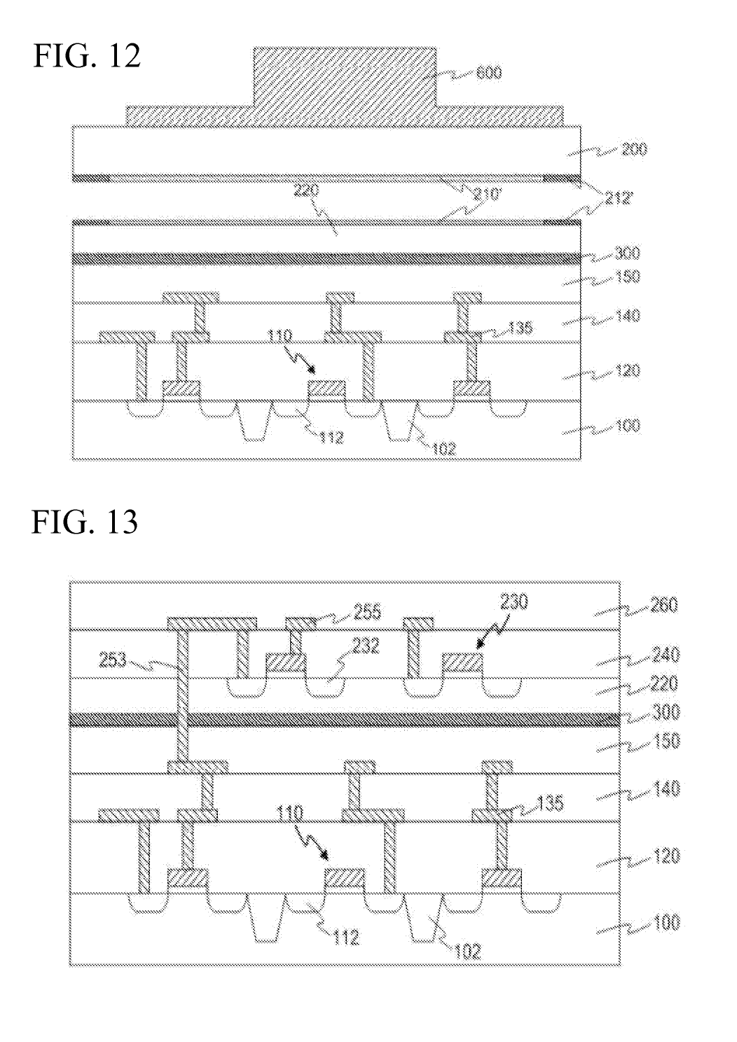

As shown in FIG. 12, a vacuum chuck 600 is used to suck to the second semiconductor substrate 200 on the single crystalline epitaxial layer 220, to detach the second semiconductor substrate 200. After detaching the second semiconductor substrate 200 from the top of the single crystalline epitaxial layer 220, the detaching layer 210 and the ion-implanted layer 212 can be remained on the single crystalline epitaxial layer 220. The surface of the single crystalline epitaxial layer 220 can be treated subsequently. A grinding or polishing process can be performed to the surface of the single crystalline epitaxial layer 220 in order to remove the detaching layer 210 and the ion-implanted layer 212 that are remained on the single crystalline epitaxial layer 220. In other method, the surface of the single crystalline epitaxial layer 220 can be etched isotropic or anisotropic. For example, wet-etching the single crystalline epitaxial layer 220 using diluted Hydrofluoric acid, a naturally grown oxide or contaminations on the surface can be removed.

In FIG. 13, a active region is defined in the single crystalline epitaxial layer 220 which is bonded on a third interlayer dielectric film 150, and upper semiconductor devices are formed on the single crystalline epitaxial layer 200. For example, as upper semiconductor devices, wirings, interconnections, capacitors, diodes and/or memory devices can be formed.

As a following step, a fourth interlayer dielectric film 240 is formed to cover the transistors on the single crystalline epitaxial layer 220.

Contacts and wirings 255 can be formed in the fourth interlayer dielectric film 120. Also, contact plugs 253, which are electrically connected to the lower region semiconductor devices by penetrating the fourth interlayer dielectric film 120 and the single crystalline epitaxial layer 220, can be formed.

After forming lower region semiconductor devices, a fifth interlayer dielectric film 260 is formed by depositing isolation material.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

1. A method for fabricating semiconductor substrate, comprising:
providing a first semiconductor substrate, which includes a detaching layer spaced from an upper surface of the first semiconductor substrate;
forming an ion-implanted layer proximate to an edge of the detaching layer;
bonding a second semiconductor substrate to the first semiconductor substrate;
forming a crack in the ion-implanted layer in response to applying stress to the ion-implanted layer; and
detaching a portion of the first semiconductor substrate in response to cleaving through the crack.

2. The method of claim 1, wherein the detaching layer is a porous layer.

3. The method of claim 1, wherein providing the first semiconductor substrate comprises:
providing a single crystalline semiconductor substrate;
forming a detaching layer on the surface of the single crystalline semiconductor substrate; and
forming a single crystalline epitaxial layer on the detaching layer.

4. The method of claim 3, wherein the second semiconductor substrate is bonded to surface of the single crystalline epitaxial layer.

5. The method of claim 1, wherein the ion-implanted layer is formed in ring shaped along to the edge boundary of the first semiconductor substrate.

6. The method of claim 1, wherein forming the ion-implanted layer comprises, forming a mask pattern on the first semiconductor substrate which exposes edge boundary of the first semiconductor substrate; and forming the ion-implanted layer by ion-implanting hydrogen ions into the edge boundary of the detaching layer using the mask pattern.

7. The method of claim 6, wherein forming the mask pattern is positioning a mechanical device which exposes the edge boundary of the first semiconductor substrate.

8. The method of claim 1, wherein forming the detaching layer on the first semiconductor substrate is further included before bonding to the second semiconductor substrate.

9. The method of claim 1, wherein adding stress to the ion-implanted layer includes heating sidewall of the ion-implanted layer or adding physical shock to the sidewall of the ion-implanted layer.

10. The method of claim 1, wherein adding stress to the ion-implanted layer includes uniformly irradiating laser around sidewall of the ion-implanted layer or uniformly injecting waterjet around sidewall of the ion-implanted layer.

11. The method of claim 9, wherein heating sidewall of the ion-implanted layer includes heating sidewall of the ion-implanted layer at the temperature of 350 to 600 degree Celsius.

12. The method of claim 1, wherein the method further includes treating remnant of the first semiconductor substrate on the second semiconductor substrate, which is remained after detaching a portion of the first semiconductor.

13. The method of claim 12, wherein the treating remnant of the first semiconductor substrate includes polishing or etching surface of the first semiconductor substrate remaining on the second semiconductor substrate.

14. A method for fabricating semiconductor device, comprising:
providing a first semiconductor substrate, which includes a detaching layer proximate to a pre-defined depth from a surface of the first semiconductor substrate;
forming an ion-implanted layer proximate to the edge of the detaching layer;
bonding a second semiconductor substrate to the surface of the first semiconductor substrate, wherein the second semiconductor substrate includes a semiconductor device and an isolation layer which covers the semiconductor device;
applying stress to the ion-implanted layer;
cleaving through the ion-implanted layer to remove a portion of the first semiconductor substrate; and
forming a second semiconductor device on the portion of the first semiconductor substrate.

15. The method of claim 14, wherein the detaching layer includes porous silicon.

16. The method of claim 14, wherein providing the first semiconductor substrate includes, providing a single crystalline semiconductor substrate; forming a detaching layer on the surface of the single crystalline semiconductor substrate; and forming single crystalline epitaxial layer on the detaching layer.

17. The method of claim 14, wherein the ion-impanted layer is formed in ring shaped along to the edge boundary of the first semiconductor substrate.

18. The method of claim 14, wherein forming the ion-implanted layer includes, forming a mask pattern which exposes edge boundary of the first semiconductor substrate on the first semiconductor substrate; and forming the ion-implanted layer by ion-implanting hydrogen ions into the edge boundary of the detaching layer using the mask pattern.

19. The method of claim 18, wherein forming the mask pattern is positioning a mechanical device which exposes the edge boundary of the first semiconductor substrate.

20. The method of claim 14, wherein bonding the second semiconductor substrate to the surface of the first semiconductor substrate is bonding the isolation layer on the second semiconductor substrate and surface of the first semiconductor substrate.
